(19) United States
(12) Patent Application Publication
(10) Pub. No.: US 2023/0297931 A1
(43) Pub. Date: Sep. 21, 2023

(54) SERVICE MANAGEMENT METHOD AND SERVICE MANAGEMENT DEVICE

(71) Applicant: TOYOTA JIDOSHA KABUSHIKI KAISHA, Toyota-shi (JP)

(72) Inventors: Nobuhisa OTSUKI, Edogawa-ku (JP); Tomoyuki Kaga, Mishima-shi (JP); Hiroya Matsubayashi, Koto-ku (JP); Yuki Ichioka, Kawasaki-shi (JP); Takumi Ban, Setagaya-ku (JP); Hideo Hasegawa, Nagoya-shi (JP)

(73) Assignee: TOYOTA JIDOSHA KABUSHIKI KAISHA, Toyota-shi (JP)

(21) Appl. No.: 18/175,235

(22) Filed: Feb. 27, 2023

(30) Foreign Application Priority Data
Mar. 15, 2022 (JP) 2022-040397

(51) Int. Cl. G06Q 10/067; G06F 30/20

(52) U.S. Cl. CPC G06Q 10/067; G06F 30/20

(57) ABSTRACT

A simulation is performed using a digital space reproduced based on a real space in which a service is provided. Based on a simulation result satisfying a predetermined convergence condition, a threshold for detecting occurrence of an abnormality in one or more works performed in association with provision of the service in the real space may be set for each work unit corresponding to the one or more works. When the threshold is set, the time difference between the preset standard working time and the simulated work time included in the simulation result satisfying the convergent condition is calculated. A larger threshold value is assigned to a work unit having a larger time difference than a work unit having a smaller time difference.

The present application claims priority under 35 U.S.C. §119 to Japanese Patent Application No. 2022-040397, filed on Mar. 15, 2022, the contents of which application are incorporated herein by reference in their entirety.

### TECHNICAL FIELD

The present disclosure relates to a method and device for managing a service provided by a business operator to a business customer.

### BACKGROUND ART

JP2007-041950A discloses a system in which a simulation for management of a production line is executed. This prior art system has a plurality of models to execute the simulation. These models are constructed based on actual data in the actual production line or predicted data in the actual production line. The prior art system also records information such as components of the actual production line, past simulation results using the model corresponding to the production line, etc. When the simulation of a new production line, the model suitable for the simulation of the new production line is specified from the plurality of models based on the recorded information.

In addition to JP2007-041950A, the documents showing the technical level of the technical field relevant to the present disclosure include JP2019139319A, JP2004-086358A and JP2018-005550A.

Consider a case where a model suitable for a new production line has been identified in the prior art system. The result of the simulation using this appropriate model is compared to the actual data in the new production line. If the simulation result and the actual data deviate from each other, it is determined that an abnormality has occurred in the new production line.

Here, a cause of an occurrence of the abnormality in the new production line will be considered. In the production line, various works are performed by a cooperation of a plurality of work subjects (i.e., a plurality of persons and / or a plurality of robots). The various works are affected by external factors in addition to internal factors such as the processing capability of the work entity and contents of the work. The various works include not only works having high resistance (robustness) to an external factor but also works having low resistance to the external factor.

In the simulations of the prior art system, no distinction is made between the internal and external factors. Therefore, when the actual data in the new production line is greatly affected by the external factor, there is a possibility that occurrence of the abnormality in the production line cannot be correctly detected. This problem is not limited to production lines, but is common to a work cooperation type system that are susceptible to the external factor. Accordingly, improvements are desired to increase a detection accuracy of the occurrence of the abnormality in such systems.

The present disclosure has been made in view of the above problem. An object of the present disclosure is to provide a technique capable of improving the detection accuracy in a case where an occurrence of an abnormality in a work cooperation type system in which various works are performed in cooperation with each other is detected using a result of a simulation.

### SUMMARY

A first aspect of the present disclosure is a method to manage a service provided from a business operator to a business customer, and has the following features.

The method comprises the steps of:
executing a simulation using a digital space reproduced based on a real space in which the service is provided;
repeating the simulation until a simulation result satisfying a predetermined convergence condition is obtained; and
setting a threshold to detect an occurrence of an abnormality in one or more works related to the provision of the service in the real space for each work unit corresponding to the one or more works based on the simulation result in which the convergent condition is satisfied.

The step of setting the threshold comprises the steps of:
calculating, for each work unit, a simulation time difference indicating a time difference between a preset standard working time and a simulated work time included in the simulation result satisfying the convergent condition; and
setting a threshold corresponding to the simulation time difference to the work unit, wherein the work unit having a larger simulation time difference is given a threshold larger than that of the work unit having a smaller simulation time difference.

A second aspect of the present disclosure further has the following feature in the first aspect.

The work unit includes a batch work unit defined with respect to multiple works performed by a plurality of work subjects and an individual work unit defined with respect to individual works constituting the multiple works.

The method further comprises the steps of:
calculating an actual work time in the one or more works for each work unit while the service is provided in the real space;
calculating a real time difference indicating a time difference between an actual work time of the batch or individual work unit and a standard working time preset for the batch or individual work unit; and
determining that an abnormality occurs in the individual work unit when the real time difference in the batch work unit is greater than the threshold set for the batch work unit and the real time difference in the individual work unit is greater than the threshold set for the individual work unit.

A third aspect of the present disclosure further has the following feature in the first aspect.

The work unit includes a batch work unit defined with respect to multiple works performed by the plurality of work subjects and an individual work unit defined with respect to individual works constituting the multiple works.

The method further comprises the steps of:
calculating an actual work time in the one or more works for each work unit while the service is provided in the real space;
calculating a real time difference indicating a time difference between an actual work time of the batch or individual work unit and a standard working time preset for the batch or individual work unit; and
determining that an abnormality occurs in the batch work unit when the real time difference in the batch work unit is greater than the threshold set for the batch work unit and the real time difference in the individual work unit is less than the threshold set for the individual work unit.

A fourth aspect of the present disclosure further has the following feature in the second aspect.

The method further comprises the steps of:
when it is determined that the abnormality occurs in the individual work unit or the batch work unit, performing redistribution of resources to be input to the one or more works;
repeating the simulation until a new simulation result satisfying the convergent condition is obtained by using the digital space in which the resource reallocation is performed; and
resetting the threshold for each work unit based on the new simulation result.

A fifth aspect of the present disclosure is a device to manage a service provided from a business operator to a business customer, and has the following features.

The device includes a processor.

The processor is configured to:
execute processing to simulate using a digital space reproduced based on a real space in which the service is provided;
execute processing to repeat the simulation until a simulation result satisfying a predetermined convergence condition is obtained; and
execute processing to set a threshold for detecting an occurrence of an abnormality in one or more works related to the provision of the service in the real space for each work unit corresponding to the one or more works based on the simulation result in which the convergent condition is satisfied.

In the processing to set the threshold, the processor is further configured to:
execute processing to calculate, for each work unit, a simulation time difference indicating a time difference between a preset standard working time and a simulated work time included in the simulation result satisfying the convergent condition; and
execute processing to set a threshold corresponding to the simulation time difference to the work unit.

In the processing to set the threshold, the work unit having a large simulation time difference is assigned a threshold larger than that of the work unit having a small simulation time difference.

A sixth aspect of the present disclosure further has the following feature in the fifth aspect.

The work unit includes a batch work unit defined with respect to multiple works performed by a plurality of work subjects and an individual work unit defined with respect to individual works constituting the multiple works.

The processor is further configured to:
execute processing to calculate an actual work time in the one or more works for each work unit while the service is provided in the real space;
execute processing to calculate a real time difference indicating a time difference between an actual work time of the batch or individual work unit and a standard working time preset for the batch or individual work unit; and
execute processing to determine that an abnormality has occurred in the individual work unit when the real time difference in the batch work unit exceeds the threshold set for the batch work unit and the real time difference in the individual work unit exceeds the threshold set for the individual work unit.

A seventh aspect of the present disclosure further has the following feature in the fifth aspect.

The work unit includes a batch work unit defined with respect to multiple works performed by the plurality of work subjects and an individual work unit defined with respect to individual works constituting the multiple works.

The processor is further configured to:
execute processing to calculate an actual work time in the one or more works for each work unit while the service is provided in the real space;
execute processing to calculate a real time difference indicating a time difference between an actual work time of the batch or individual work unit and a standard working time preset for the batch or individual work unit; and
execute processing to determine that an abnormality has occurred in the batch work unit when the real time difference in the batch work unit exceeds the threshold set for the batch work unit and the real time difference in the individual work unit is less than the threshold set for the individual work unit.

An eighth aspect of the present disclosure further has the following feature in the sixth aspect.

The processor is further configured to:
execute processing to redistribute resources to be input to the one or more works when it is determined that the abnormality has occurred in the individual work unit or the batch work unit;
execute processing to repeat the simulation until a new simulation result satisfying the convergent condition is obtained by using the digital space in which the resource reallocation is performed; and
execute processing to reset the threshold for each work unit based on the new simulation result.

According to the first or fifth aspect, the threshold for detecting the occurrence of the abnormality in one or more works performed in association with the provision of the service in the real space is set for each work unit corresponding to one or more works. When the threshold is set, the time difference (i.e., the simulation time difference) between the preset standard working time and the simulated work time included in the simulation result satisfying the convergent condition is calculated.

When the simulation time difference is large, it means that the works constituting the work unit have low resistance to the external factor. In this regard, according to the first or fifth aspect, the larger threshold is assigned to the work unit having the larger simulation time difference than that having the smaller simulation time difference. Therefore, in the case where multiple works are performed by the cooperation of the plurality of work subjects, it is possible to detect the occurrence of the abnormality in the work unit with high accuracy.

According to the second or sixth aspect, when the real time difference in the batch work unit exceeds the threshold set for the batch work unit and the real time difference in the individual work unit exceeds the threshold set for the individual work unit, it is possible to determine that the abnormality has occurred in the individual work unit.

According to the third or seventh aspect, when the real time difference in the batch work unit exceeds the threshold set for the batch work unit and the real time difference in the individual work unit falls below the threshold set for the individual work unit, it can be determined that the abnormality has occurred in the batch work unit.

According to the fourth or eighth aspect, when it is determined that the abnormality has occurred in the individual or batch work unit, the reallocation of the resources to be input to one or more works is performed, and the simulation is repeated until the new simulation result satisfying the convergent condition is obtained. Therefore, even if the abnormality occurs in the individual or batch work unit, the abnormal state can be quickly eliminated.

### BRIEF DESCRIPTION OF DRAWINGS

FIG. 1 is a diagram illustrating a concept of services related to logistics, which is an example of a service provided by a business operator to a business customer;

FIG. 2 is a diagram illustrating a specific example of the transport delivery system illustrated in FIG. 1 and a configuration example of a real space in which services related to logistics are provided;

FIG. 3 is a diagram illustrating an example of a work unit defined in a digital space;

FIG. 4 is a diagram illustrating an example of a total work time for a product in a batch work unit and a standard working time to be compared with the total work time when multiple works continuously performed in the digital space illustrated in FIG. 3 are set as the batch work unit;

FIG. 5 is a diagram illustrating an example of a relationship between a simulation time difference and a threshold;

FIG. 6 is a diagram illustrating a configuration example of a management device related to setting processing of a threshold; and

FIG. 7 is a diagram illustrating a configuration example of the management device related to determination processing of an occurrence of an abnormality.

### DESCRIPTION OF EMBODIMENT

Hereinafter, a management method and a management device for a service according to an embodiment of the present disclosure will be described with reference to drawings. The management method according to the embodiment is realized by computer processing performed in the management device according to the embodiment. In the drawings, the same or corresponding parts are denoted by the same reference numerals, and the description thereof will be simplified or omitted.

### 1. Example of Service

A management device according to an embodiment is a device for managing a service provided by a business operator (vendor) to a business customer. In the embodiment, a case where a service provided by the business operator to the business customer is “a service related to logistics” (hereinafter, also referred to as a “logistics service”) will be described as an example. In the logistics service, various works for delivering a product (products) or a good (goods) requested by the business customer to the business customer is performed. The “business operator” may be a private operator or a corporate operator. When the “business operator” is a corporate business operator, the “business operator” may be constituted by a single company or may be an aggregate of a plurality of companies. The “business customer” includes not only an individual customer but also a corporate customer.

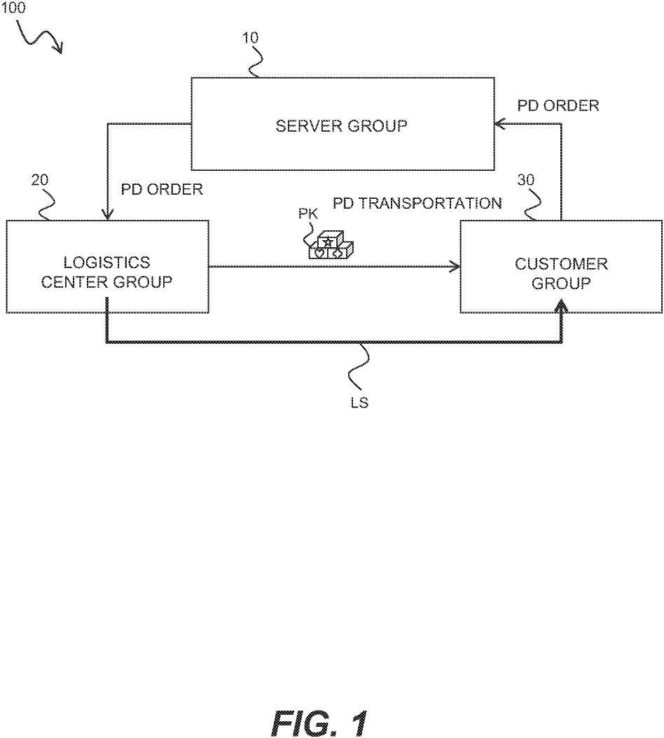

FIG. 1 is a diagram illustrating the concept of a logistics service. FIG. 1 illustrates a TMS system (transportation management system) 100 as an example of a system for providing logistics delivery. In the example shown in FIG. 1, the TMS system 100 is depicted that includes a server group 10, a logistics center group 20, and a business customer group 30. The server group 10 is composed of a plurality of servers. Each server constituting the server group 10 is directly or indirectly connected to each computer of the logistics center group 20 and the business customer group 30 via a network (not shown).

Some or all of the servers constituting the server group 10 are managed by, for example, a business operator who controls the “services related to logistics”. One of the servers constituting the server group 10 receives a product PD order information from a computer of the business customer belonging to the business customer group 30. The order information includes, for example, a number, a destination, and a scheduled delivery date of the product PD. The server that has received an order for product PD places the order for product PD to a computer of any of the logistics centers (for example, a logistics center close to the delivery destination of product PD) constituting the logistics center group 20. This order information includes, for example, the same information as the information constituting the order information accepted by the server.

The computer of the logistics center that has received the order of the product PD checks, for example, the stock of the product PD. If there is a product PD inventory, the logistics center computer performs processing to deliver the product PD. If there is no stock in the product PD, a computer at the logistics center executes processing to replenish the product PD. Examples of the processing to replenish the product PD include an ordering to a producer and an ordering to other logistics centers.

The computer at the logistics center transmits a work instruction such as picking and process for delivery of the product PD to a work robot, a mobile terminal of a worker, and the like in the logistics center in the processing to perform a delivery of the product PD. In the processing to deliver the product PD, an instruction for loading work of a package box PK containing the product PD into a mobile body is transmitted to the work robot or the like. In the processing to deliver the product PD, information on a destination of the product PD, information on a route to the destination, and the like are further transmitted to the mobile body loaded with the package box PK.

### 2. Simulation Using Digital Space

### 2-1. Real Space

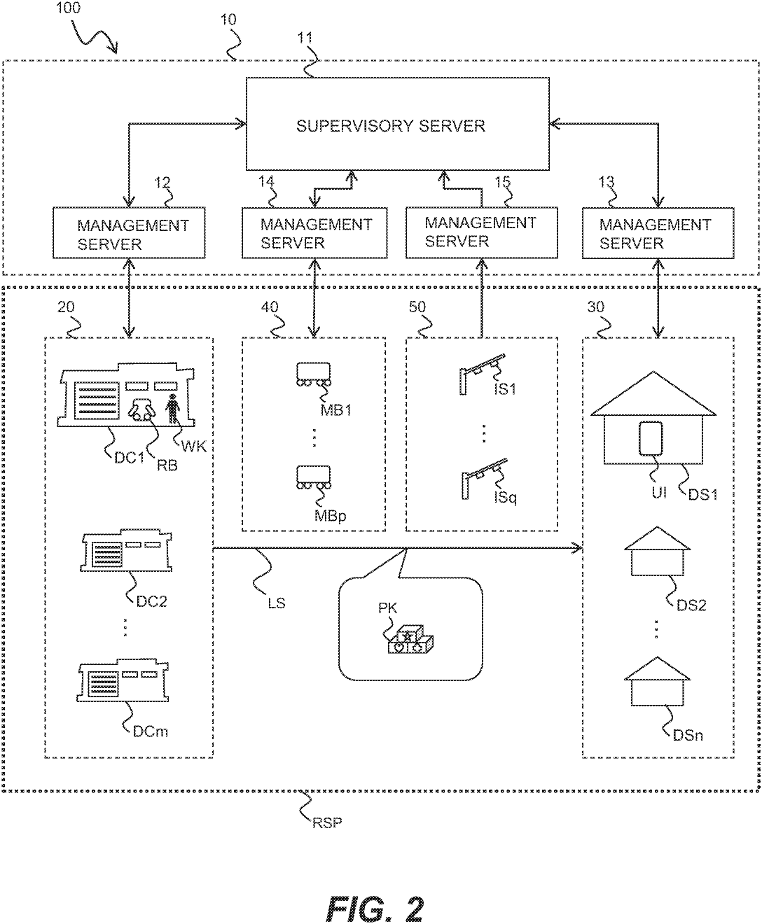

In the embodiment, a simulation (hereinafter, also referred to as a “digital twin simulation” or a “DTS”) using a digital space in which the logistics service LS described in FIG. 1 is provided is executed. The digital space is reproduced based on a real space in which the logistics service LS is provided. FIG. 2 is a diagram illustrating an example configuration of the TMS system 100 illustrated in FIG. 1 and the real space in which a logistics service LS is provided.

In the example shown in FIG. 2, the server group 10 includes a supervisory server 11 and management servers 12 to 15. The supervisory server 11 supervises the management servers 12 to 15. The management server 12 is assigned to a logistics center group 20. The management server 13 is assigned to a business customer group 30. The management server 14 is assigned to a mobile body group 40. The management server 15 is assigned to an infrastructure group 50. The logistics center group 20, the business customer group 30, the mobile body group 40, and the infrastructure group 50 are entities, objects, or environments that exist in the real space RSP and are involved in providing the logistics service LS.

The management servers 12 to 15 transmit information to the supervisory server 11. Examples of the information transmitted from the management servers 12 to 15 to the supervisory server 11 include various types of information collected by each management server from a group (such as the logistics center group 20) assigned to the management server. These pieces of information are stored in a database included in the supervisory server 11 and used for the DTS.

The management servers 12 and 14 also receive information from the supervisory server 11. Examples of the information received from the supervisory server 11 include allocation information on the resources (assets) to be put into a work performed in relation to a provision of the logistics service LS. The allocation information is generated based on a result of the DTS (hereinafter, also referred to as a “simulation result”). The management server 13 receives information on a delivery status of the product PD from the supervisory server 11. The information on the delivery status is generated based on, for example, the information on the delivery status of the product PD received by the supervisory server 11 from the management server 12, the positional information on the mobile body received by the supervisory server 11 from the management server 14, and the like.

The logistics center group 20 includes logistics centers DC1, DC2, ..., DCm (m≥3). In the logistics center DC1, a robot RB and a worker WK that reside to engage in various works performed in the logistics center DC1. The robot RB and worker WK are “work entities” of various works performed in relation to the provision of the logistics service LS in the logistics center DC1, and are also the “resources” input to these works. Similarly to the logistics center DC1, a robot RB and a worker WK also reside in the logistics centers DC2, ..., DCm. Hereinafter, the logistics centers DC1, DC2, ..., DCm are also collectively referred to as a “logistics center DC”.

The logistics center DC exchanges various information with the management server 12. Examples of the information transmitted from the logistics center DC to the management server 12 include monitoring Information on the product PD and the work entity (i.e., the robot RB and the worker WK) in the logistics center DC. Examples of the monitoring information on the product PD include positional information on the product PD. The positional information is acquired by, for example, reading information on a wireless tag (e.g., a BLE, a RFID, or the like) attached to the product PD by a tag reader installed at each place of the logistics center DC. Examples of the monitoring information on the work entity include a state, a position, and a motion information on the work entity. These pieces of information are acquired from, for example, a visible light camera and an infrared camera installed at each place of the logistics center DC. These pieces of information may be acquired based on information on various sensors mounted on the robot RB or information on a wearable terminal worn by the worker WK.

On the other hand, examples of the information transmitted from the management server 12 to the logistics center DC include allocation information on the resources (i.e., the robot RB and the worker WK). The allocation information is information to determine the content of the work to be performed by the resources, the position in the logistics center DC at which the work is performed, the time zone at which the work is performed, and the like, and is generated based on the simulation result.

The business customer group 30 includes destinations DS1, DS2, ..., DSn (n≥3) of the product PD. The destinations DS1, DS2, ..., DSn are typically a private customer residence, a corporate customer office, a warehouse, etc. The order of the product PD is placed from a computer of the business customer belonging to the business customer group 30. Examples of the computer of the business customer include a terminal UI such as a smartphone or a tablet carried by the business customer. Hereinafter, the destinations DS1, DS2, ..., DSn are also collectively referred to as a “destination DS”.

The computer of the business customer exchanges various information with the management server 13. Examples of the information transmitted from the computer of the business customer to the management server 13 include an order information on the product PD. The order information includes, for example, number of the product PD, the destination DS, and scheduled delivery date. On the other hand, examples of the information transmitted from the management server 13 to the computer of the business customer include information related to a delivery status of the product PD.

The mobile body group 40 includes mobile body MB1, ..., MBp (p≥2) to transport the product PD from a departure point (i.e., the logistics center DC) to a destination (i.e., the destination DS). Hereinafter, the mobile body MB1, ..., MBp are also collectively referred to as a “mobile body MB”. The mobile body MB is the “work entity” of the delivery of the product PD performed in relation to the provision of the logistics service LS, and is also the “resource” input to the delivery.

The mobile body MB is configured to autonomously move on land or in the air. A travel on some or all routes from the departure point to the destination may be performed under a remote assistance by an operator. Examples of the remote assistance by the operator include remote operation of the mobile body MB, a support of an external recognition by the mobile body MB, and a support of determination regarding an action to be taken by the mobile body MB.

The mobile body MB exchanges various information with the management server 14. Examples of the information transmitted from the mobile body MB to the management server 14 include monitoring information on the mobile body MB. Examples of the monitoring information on the mobile body MB, the state and positional information on the mobile body MB. These pieces of information are acquired from various sensors mounted on the mobile body MB. Examples of the various sensors include a sensor that detects a remaining amount of a battery that supplies power to a motor that drives the mobile body MB, a sensor that detects acceleration of the mobile body MB, a sensor that detects changes in rotation angles in X, Y, and Z axis directions of the mobile body MB, and a sensor that receives radio waves from a global positioning system satellite.

On the other hand, examples of the information transmitted from the management server 14 to the mobile body MB include allocation information on the resources (i.e., the mobile body MB). This allocation information is information to determine contents of the delivery for which the mobile body MB is responsible, the destination to which the mobile body MB is directed to take the charge of this delivery (e.g., a waiting place of the logistics center DC), a time period to taking the charge of this delivery, and the like, and is generated based on the simulation result. The information transmitted from the management server 14 to the mobile body MB includes charge command information. The charge command information is generated based on the information on the remaining battery level acquired by the management server 14 from the mobile body MB. The charge command information includes, for example, a positional information on a charging facility, a positional information on a destination to which the mobile body MB is directed after a completion of the charging (e.g., the waiting place of the logistics center DC), and the like.

The infrastructure group 50 includes infrastructures IS1, ..., ISq (q≥2). The infrastructures IS1, ..., ISq are for example installed on a road provided in the real space RSP or on a construction facing this road. The infrastructures IS1, ..., ISq may be installed inside (e.g., in a room) or outside (e.g., on a roof) of a building existing in the real space RSP. Hereinafter, infrastructures IS1, ..., ISq are also collectively referred to as an “infrastructure IS”.

Examples of the infrastructure IS include a wireless communication base station, a camera having a communication function, and the like. The base station as the infrastructure IS performs wireless communication with a mobile body other than the mobile body MB (e.g., ground mobile bodies such as a walker, a bicycle and a vehicle, and aerial mobile bodies such as a drone), and detects the mobile body. The camera as the infrastructure IS performs recognition processing of an object included in a camera image, thereby detecting a mobile body other than the mobile body MB included in the camera image. The infrastructure IS generates information (e.g., congestion information, information on traffic regulation, and the like) of a road or an air route provided in the real space RSP based on the detection information on the mobile body other than the mobile body MB, and transmits the information to the management server 15. The infrastructure IS may generate information (e.g., congestion information) of a path in the building based on detection information on the mobile body other than the mobile body MB.

### 2-2. Work Unit

In the digital space reproduced based on the real space RSP, a “work unit” performed in relation to the provision of the logistics service LS is defined. In the real space RSP, multiple works are performed in association with the provision of the logistics service LS through cooperation of a plurality of work subjects. Therefore, the work unit is defined for multiple works to be performed in cooperation. However, the work unit may be defined for an individual work constituting multiple works to be performed in cooperation. Hereinafter, for convenience of description, the work unit defined for the former is also referred to as a “batch work unit”. The work unit defined for the latter is also referred to as an “individual work unit”.

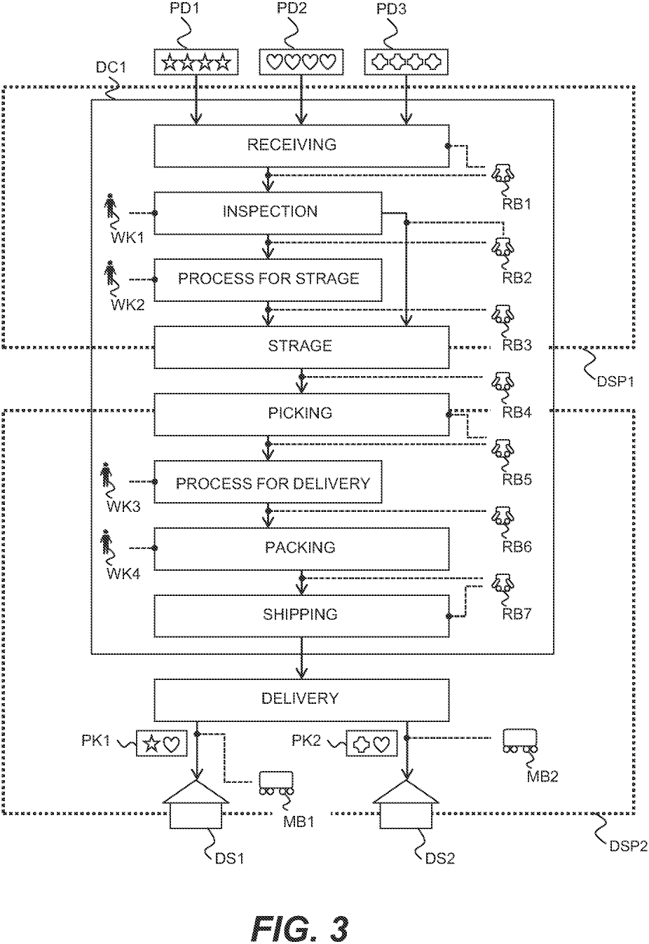

FIG. 3 is a diagram illustrating an example of a work unit defined in a digital space. FIG. 3 illustrates an example of the work performed in a logistics center DC1. In the example shown in FIG. 3, “receiving”, “inspection”, “process for storage”, “storage”, “picking”, “process for delivery”, “packing” and “shipping” take place in the logistics center DC1. The work unit is defined for the respective works.

Examples of the batch work unit performed in the logistics center DC1 include works including “receiving”, “inspection”, “process for storage”, and “storage” and works including “picking”, “process for delivery”, “packing”, and “shipping”. This is because the logistics center DC1 is a “stock-type logistics center” in which received products PD (PD1, PD2, and PD3) are once stored and a product PD is shipped in response to an order from the business customer 2. If the logistics center DC1 is a “pass-through logistics center” that mainly delivers product PD, the works of “process for storage”, “storage”, and “picking” are not performed. In this case, a batch work unit is defined for works including “receiving”, “inspection”, “process for delivery”, “packing” and “shipping”.

In the example shown in FIG. 3, the robot RB1 is responsible for “receiving” the product PD and transportation from “receiving” to “inspection” of the product PD. The worker WK1 is responsible for “inspection”, and the robot RB2 is responsible for transportation from “inspection” to “process for storage” or transportation from “inspection” to “storage”. Further, the worker WK2 is responsible for “process for storage” and the robot RB3 is responsible for transportation from “process for storage” to “storage”. The digital space DSP1 is obtained by reproducing a real space in which work from “receiving” to “storage” is performed.

In the example shown in FIG. 3, the robot RB5 is also responsible for the “picking” of the product PD and the transportation of this product PD from “picking” to “process for delivery”. Further, the worker WK3 is responsible for “process for delivery”, and the robot RB6 is responsible for transportation from “process for delivery” to “packing”. In addition, the worker WK4 is responsible for “packing”, and the robot RB7 is responsible for transportation from “packing” to “shipping” and “shipping”. In addition, the mobile body PK2 is responsible for the delivery of the package box PK1 in which the products PD1 and PD2 are accommodated, and the mobile body MB2 is responsible for the delivery of the package box PK2 in which the products PD2 and the PD3 are accommodated. The digital space DSP2 is obtained by reproducing a real space in which work from “picking” to “delivery” is performed.

### 2-3. Predetermined Convergence Condition

In the DTS, time-series information acquired by the supervisory server 11 from the management servers 12 to 15 in real time or virtually generated time-series information is input to the digital space DSP. Then, the future operation state of the logistics service when resources such as the robot RB, the worker WK, and the mobile body MB located at the logistics center DC are input to the digital space DSP and operated is simulated. The simulation result contains information about the future operation state. Examples of the information related to the future operation state include the state, position, and motion information on the work entity (robot RB and worker WK), the state and positional information on the work entity (mobile body MB), and the positional information on product PD moving in the digital space DSP.

Here, the time-series information on the location of the product PD is useful as an indicator for evaluating whether or not the logistics service LS is smoothly provided by the resources input to the digital space DSP. Therefore, in the embodiment, a total work time (hereinafter, referred to as “total work time” or “TWT”) for the product PD is calculated based on time-series information on the position of the product PD processed in the batch work unit performed in the digital space DSP. The TWT is for example calculated for every product PD processed in the batch work unit. The TWT may be calculated focusing only on a particular product PD (e.g., the product PD1). Note that if the TWT is calculated for more than one product PD, the average of these times is calculated.

Consider a batch work unit in which the first work to the last work of the multiple works continuously performed in the real space RSP are grouped together. For example, the work including “receiving”, “inspection”, “process for storage”, and “storage” described in FIG. 3 may correspond to the multiple works that are sequentially performed. In this case, “receiving” corresponds to the first work and “storage” corresponds to the last work. The work including “picking”, “process for delivery”, “packing”, “shipping”, and “delivery” is also an example of the multiple works that are performed sequentially. In this case, “picking” corresponds to the first work and “delivery” corresponds to the last work.

When the first work to the last work are grouped together, the total time required to complete all the works constituting the batch work unit can be considered as the time required to complete all the works performed in the digital space DSP reproducing the real space RSP. In the DTS, the TWT for the product PD in the batch work unit is compared with a preset standard working time (hereinafter, also referred to as “SWT_b”). Then, until a TWT shorter than SWT_b is obtained, an adjustment (an allocation) of the resources to be input to the digital space DSP, the calculation of the TWT, and the evaluation of the TWT are repeatedly performed.

The fact that TWT is shorter than SWT_b means that the “predetermined convergence condition” for DTS is satisfied. As a result of the comparison between TWT and SWT_b, if it is determined that TWT is shorter than SWT_b, the simulation result is stored. The simulation result is stored in association with, for example, information on the digital space DSP as a target of the DTS, allocation information on the resources in the digital space DSP, definition information on the batch work unit, information on a future time zone as a target of the DTS, and the like.

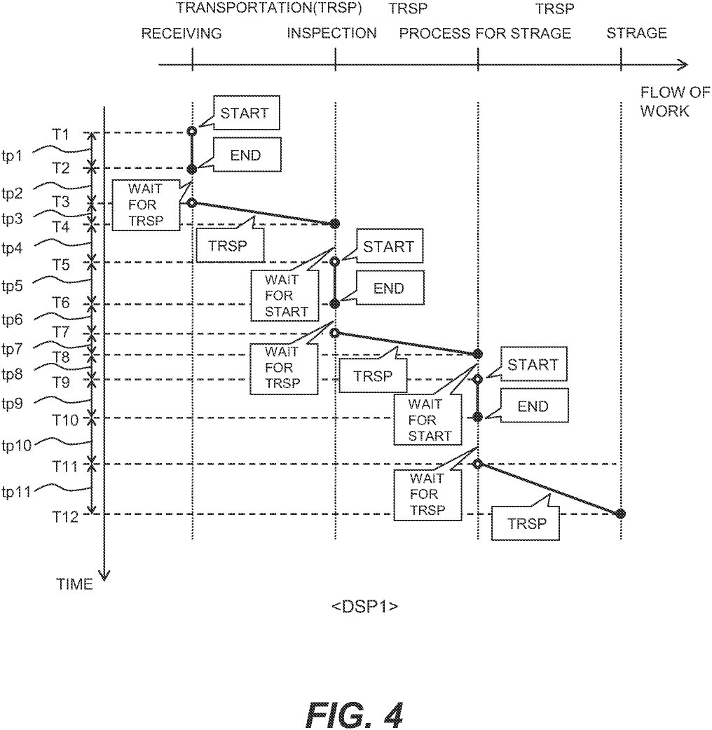

FIG. 4 is a diagram illustrating an example of TWT and SWT_b when multiple works continuously performed in the digital space DSP1 illustrated in FIG. 3 are set as a batch work unit. FIG. 4 shows the times at which one product PD is processed. In detail, “receiving” is performed between time T1 and T2, “inspection” is performed between time T5 and T6, and “process for storage” is performed between time T9 and T10. The transportation from “receiving” to “inspection” is performed between time T4 and T5, the transportation from “inspection” to “process for storage” is performed between time T7 and T8, and the transportation from “process for storage” to “storage” is performed between time T11 and T12.

Depending on the processing speed of the work entity and the allocation of resources, the product PD may wait for the start of processing. The time from time T2 to T3, the time from time T6 to T7, and the time from time T10 to T11 correspond to the time for waiting for the start of transportation. The time from time T4 to time T5 corresponds to the time for waiting for the start of “inspection”, and the time from time T8 to time T9 corresponds to the time for waiting for the start of “process for storage”.

As described above, “receiving”, “inspection”, “process for storage”, and “storage” are multiple works sequentially performed in the digital space DSP1. In addition, works associated with these works (i.e., the transportation between two consecutive works) are also multiple works consecutively performed in the digital space DSP1. Therefore, when the batch work unit for these works is defined, the elapsed time from time T1 to T12 can be calculated as TWT. If the elapsed time is shorter than SWT_b, the simulation result is saved.

In the example shown in FIG. 4, information on the digital space DSP1, allocation information on the resources in the digital space DSP1, information that a batch work unit is defined for a sequence of works from “receiving” to “storage”, and information on elapsed time from time T1 to T12 are stored as a simulation result. In addition, information related to a future time zone targeted for simulation is also added to the simulation result.

The DTS such as the calculation of the TWT in the digital space DSP2 described in FIG. 3, the determination of the convergent condition, and the adjustment (allocation) of the resources to be input to the digital space DSP2 is performed by the same method as that in the digital space DSP1 described in FIG. 4. When the convergent condition related to the DTS in the digital space DSP2 is satisfied (i.e., when it is determined that the TWT in the digital space DSP2 is shorter than the SWT_b), the simulation result is stored.

### 3. Determination of Occurrence of Abnormality

### 3-1. Threshold of Work Time

It should be noted that the sum of the work time in individual work unit tp (tp1 to tp11) corresponds to the TWT. In addition, the length of the work time tp is considered to vary depending on internal factors such as the content of work (i.e., a single work) constituting an individual work unit and the processing capacity of a work entity, but is also considered to vary depending on external factors such as a rush of product PD orders and a traffic jam on a route where a robot RD or a mobile body MB transports product PD.

Therefore, in the embodiment, “threshold TH” is set to work time in individual work unit based on the length of the work time tp in individual work unit when the simulation result is stored. In the setting of the threshold TH, first, a standard working time (hereinafter, also referred to as “SWT_i”) in an individual work unit is calculated based on internal factors that affect works constituting the individual work unit. Subsequently, a time difference (simulation time difference) Δts between the work time tp in individual work unit when the TWT is determined to be shorter than the SWT_b and the SWT_i in this individual work unit is calculated.

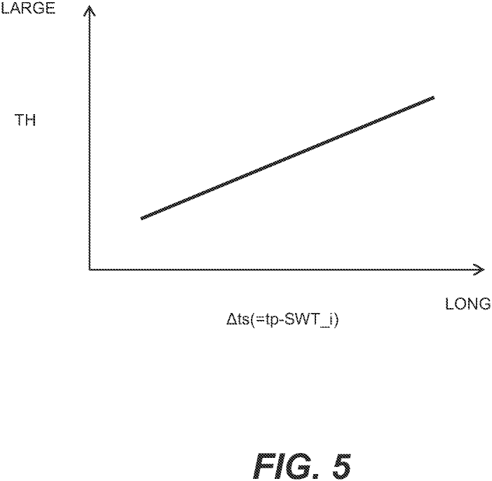

When the time difference Δts is small, it means that the work constituting the individual work unit has high resistance to external factors, and when the time difference Δts is large, it means that the work constituting the individual work unit has low resistance to external factors. For example, the threshold TH is set so that the threshold TH increases as the time difference Δts increases. FIG. 5 is a diagram showing an example of the relationship between the time difference Δts and the threshold TH. In the example shown in FIG. 5, the value of the threshold TH increases in proportion to the time difference Δts (= tp-SWT_i).

### 3-2. Determination Using Threshold TH

In the embodiment, occurrence of an abnormality in work performed in association with provision of the logistics service LS in the real space RSP is detected using the threshold TH set according to the time difference Δts. The occurrence of the abnormality is detected by focusing on the individual work unit in which the threshold TH is set. As described above, in the real space RSP, monitoring Information of work entities (i.e., robot RB, worker WK, and mobile body MB) engaged in work performed in relation to provision of the logistics service LS is acquired. Then, an actual work time (hereinafter, also referred to as “AWT”) in an individual work unit is calculated based on the monitoring information, and a time difference (real time difference) Δta between the AWT and a standard working time (i.e., the SWT_i) in the individual work unit is calculated.

When the time difference Δta exceeds the threshold TH, there is a high probability that an abnormality has occurred in the individual work unit. However, it is expected that the time difference Δta individual work unit is temporarily increased, it is expected that the time difference Δta will exceed the threshold TH, but it is also expected that this high load state will be resolved in the near future. Therefore, in the embodiment, when it is determined that an abnormality has occurred in a certain individual work unit, the time difference Δta is calculated further focusing on the batch work unit including this individual work unit.

The time difference Δta in the batch work unit can be calculated based on, for example, the AWT in the batch work unit and the standard working time in the batch work unit. The threshold TH (TH_b) of the batch work unit is calculated, for example, by integrating the standard working times of the individual work units constituting the batch work unit. It should be noted that the threshold TH (TH_b) of the batch work unit obtained by bundling the first work to the last work of the multiple works continuously performed in the real space RSP is the same value as the above-described SWT_b. In the embodiment, when the time difference Δta exceeds the threshold TH in both the individual work unit and the batch work unit, it is determined that an abnormality has occurred in the individual work unit.

Here, even if it is determined that no abnormality has occurred in a certain individual work unit, there may be a case where an abnormality occurs in a batch work unit including this individual work unit. Therefore, in the embodiment, the time difference Δta may be calculated by further focusing on a batch work unit including a certain individual work unit regardless of a result of determination of abnormality in works constituting the individual work unit. Then, when the time difference Δta is less than the threshold TH (TH_i) in the individual work unit but the time difference Δta is greater than the threshold TH (TH_b) in the batch work unit, it may be determined that an abnormality has occurred in the batch work unit.

As described above, according to the embodiment, the threshold TH is set in accordance with the tolerance to external factors. Therefore, in a case where multiple works are performed in cooperation with a plurality of work subjects, it is possible to detect occurrence of an abnormality in an individual work unit or a batch work unit with high accuracy.

### 4. Configuration Example of Management Device

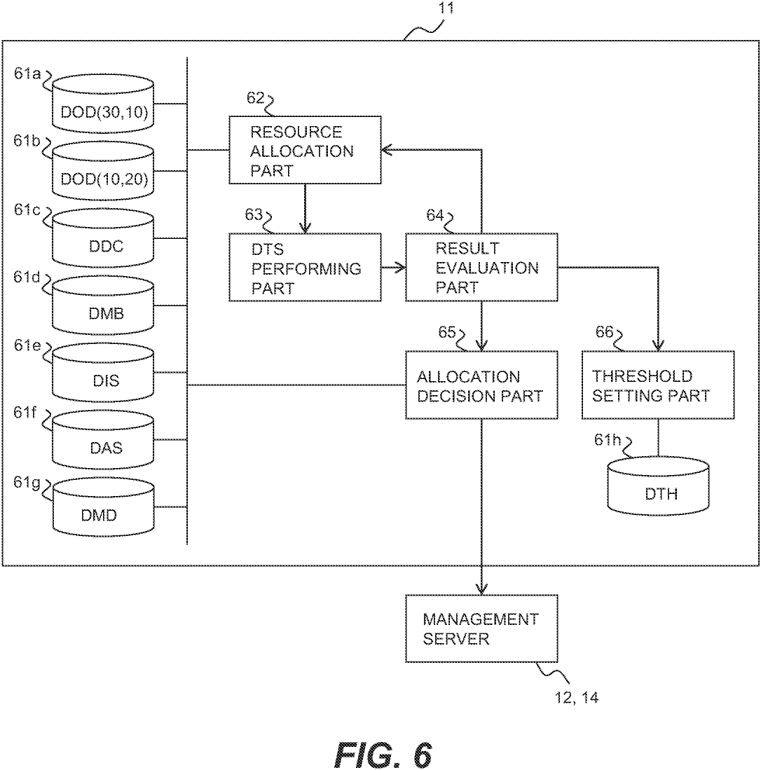

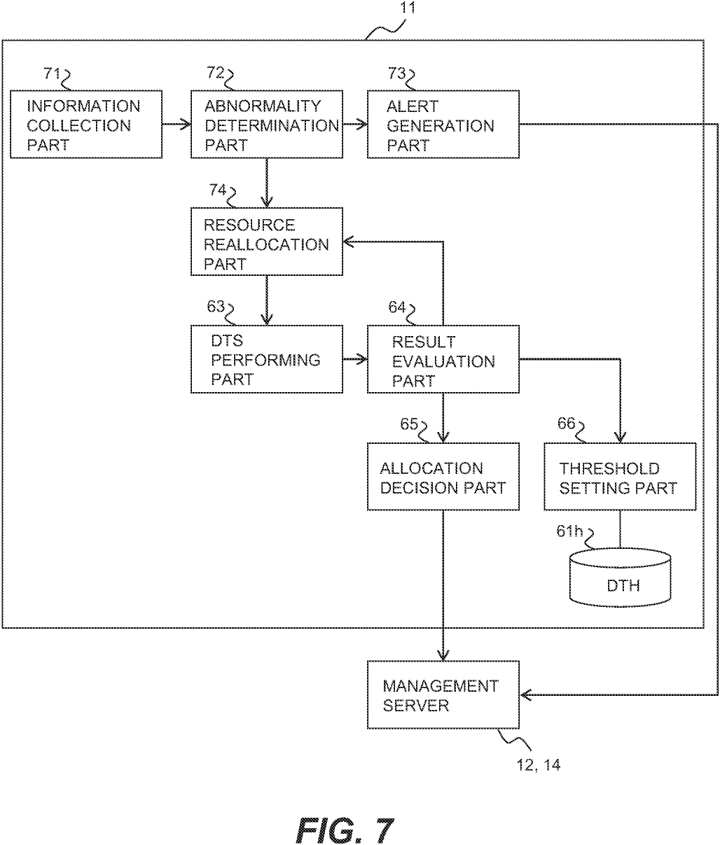

Next, a specific configuration example of the management device according to the embodiment will be described with reference to FIGS. 6 and 7. FIG. 6 illustrates a configuration example of a management device related to setting processing of a threshold TH.

In the example illustrated in FIG. 6, the supervisory server 11 includes various databases 61a to 61h, a resource allocation part 62, a DTS performing part, a result evaluation part 64, an allocation decision part 65, and a threshold setting part 66. The functional portions 62 to 66 shown in FIG. 6 are realized by the processor included in the supervisory server 11 executing a predetermined program stored in the memory device of the supervisory server 11.

The various databases 61a to 61h are formed in a predetermined area of the memory device of the supervisory server 11. An order information DOD (30, 10) of the product PD transmitted from a business customer is stored in the database 61a. The order information (30, 10) is information transmitted from the computer of the business customer to the supervisor server 11 via the management server 13. The order information (30, 10) may be virtually generated in the supervisory server 11 or the external server.

An order information DOD (10, 20) of the product PD transmitted from the supervisory server 11 to the logistics center DC via the management server 12 is stored in the database 61b. The order information (10, 20) may be virtually generated in the supervisory server 11 or the external server.

The database 61c stores the information DDC of the logistics center DC received from the management server 12. The information DDC may be virtually generated in the supervisory server 11 or the external server. The information DDC includes monitoring Information of product PD and work entity (i.e., the robot RB and the worker WK) at logistics center DC. Examples of the monitoring information on the product PD include positional information on the product PD. Examples of the monitoring information on the work entity include a state, a position, and a motion information on the work entity.

The database 61d stores mobile body MB information DMB received from the management server 14. The information DMB may be virtually generated in the supervisory server 11 or the external server. The information DMB includes monitoring information on the mobile body MB. As the monitoring information on the mobile body MB, the state and positional information on the mobile body MB are exemplified.

The database 61e stores information DISs received from the management server 15. The information DIS may be virtually generated in the supervisory server 11 or the external server. The information DIS includes detection information on the mobile body by the infrastructure IS, information on a road and an air route provided in the real space RSP, and the like.

The database 61f stores resource information DAS. The information DAS includes information (resource information) of a resource that can be input to work performed in relation to provision of the logistics service LS and information (allocation information) of a resource generated based on a simulation result. The resource information and the allocation information are set for each space (for example, DSP1 and DSP2) of the digital space DSP, for example.

The database 61g stores information DMD of various models used for execution of the DTS. Examples of the various models include a behavior model constructed in consideration of contents of work performed in relation to the provision of the logistics service LS in the real space RSP, the motion of the work entity, the behavior of the mobile body other than the work entity, and the like. In order to appropriately represent the latest state of the real space RSP, the various models are periodically verified and appropriately updated.

The database 61h stores information DTH on the threshold TH of the work time. This threshold TH is set for each individual and batch work unit. The threshold TH may be associated with definition information on individual and batch work units and information related to a future time zone. The definition information on the individual and batch work unit is associated with the threshold TH, so that the threshold TH can be easily specified. Since the information related to the future time zone is associated with the threshold TH, it is possible to detect the occurrence of the abnormality in which the threshold TH is switched according to the future time zone in which the individual work unit or the batch work unit is performed.

The resource allocation part 62 adjusts resources to be input to the digital space DSP. The adjustment of the resources is performed by arbitrarily allocating the resources within a range in which the digital space DPS in which the DTS is performed can be input to the individual work unit and the batch work unit based on the resource information stored in the database 61f. In order to increase the satisfaction of the convergent condition, allocation information generated based on past simulation results may be used when adjusting the resources. The resource allocation part 62 transmits information on the adjusted resource to the DTS performing part 63.

The DTS performing part 63 performs DTS. The execution of the DTS is performed on, for example, a space of one section of the digital space DSP. In this case, various models used for executing the DTS for one section of the digital space DSP are extracted from the database 61g. Then, resource information received from the resource allocation part 62 and time-series information acquired in real time from the management servers 12 to 15 are input to these models. Instead of real-time information, virtually generated time-series information may be input to these models.

Then, the TWT is calculated in a batch work unit in which the first work to the last work of the multiple works continuously performed in one section of the digital space DSP are grouped. The DTS performing part 63 transmits this TWT to the result evaluation part 64 together with the information on the digital space DSP targeted by the DTS.

The result evaluation part 64 compares the TWT received from the DTS performing part 63 with the SWT_b. If TWT is shorter than SWT_b, the result evaluation part 64 determines that the convergent condition is satisfied, and transmits the simulation result to the allocation decision part 65 and the threshold setting part 66. Otherwise, the result evaluation part 64 sends a resource readjustment instruction to the resource allocation part 62. In this case, the resource allocation part 62 readjusts the resources to be input to the digital space DSP, and the DTS performing part 63 performs the DTS based on information on the readjusted resource.

Based on the simulation result received from the result evaluation part 64, the allocation decision part 65 generates allocation information on the resources to be input to the real space RSP of the future time zone, and transmits the allocation information on the resources to the management servers 12 and 14. In this case, the management servers 12 and 14 perform allocation of a new resource, conversion of an already allocated resource, and the like based on the allocation information. The allocation decision part 65 also writes the allocation information on the decided resource into the database 61f.

The threshold setting part 66 sets from the result evaluation part 64, the threshold setting part 66 sets a threshold TH for the work time in the individual and batch work units in the future time zone. The threshold TH (TH_i) of the individual work unit is, for example, a value obtained by multiplying the time difference Δts in the individual work unit described in FIG. 4 by a coefficient k (k> 1.0) corresponding to the magnitude of the time difference Δts (TH_i = Δts·k). The threshold TH (TH_b) of the batch work unit is, for example, an integrated value of the threshold TH of the individual work unit (TH_b = ΣΔts·k). The threshold setting part 66 also writes information on the set threshold TH in the database 61h.

FIG. 7 is a diagram illustrating a configuration example of a management device related to determination processing of occurrence of an abnormality. In the example shown in FIG. 7, the supervisory server 11 includes an actual information collection part 71, an abnormality determination part 72, an alert generation part 73, and a resource reallocation part 74. The functional portions 71 to 74 illustrated in FIG. 7 are realized by the processor included in the supervisory server 11 executing a predetermined program stored in the memory device of the supervisory server 11.

The actual information collection part 71 collects time-series information acquired in real time from the management servers 12 to 15. This real-time information is composed of information transmitted by the logistics center group 20, business customer group 30, mobile body group 40, and infrastructure group 50 to the management servers assigned to these groups.

The abnormality determination part 72 calculates the actual work time (i.e., the AWT) in individual and batch work units based on the real-time information collected by the actual information collection part 71. The calculation of the AWT is performed by focusing on the batch work unit in which the threshold TH is set and the individual work units included in the batch work unit. When the AWT is calculated, the abnormality determination part 72 calculates the time difference Δta based on the AWT and the standard working times (i.e., SWT_i and SWT_b) corresponding to the individual work unit and the batch work unit.

When the time difference Δta is calculated, the abnormality determination part 72 compares the time difference Δta with the threshold TH. When the time difference Δta in the individual work unit exceeds the threshold TH (TH_i) and the time difference Δta in the batch work unit exceeds the threshold TH (TH_d), the abnormality determination part 72 determines that an abnormality has occurred in the individual work unit. When the time difference Δta in the individual work unit is lower than the threshold TH (TH_i) and the time difference Δta in the batch work unit is higher than the threshold TH (TH_d), the abnormality determination part 72 may determine that an abnormality has occurred in the batch work unit.

When it is determined that an abnormality has occurred, the abnormality determination part 72 generates abnormality occurrence information and transmits it to the alert generation part 73. The abnormality occurrence information includes, for example, information on the time at which the abnormality occurred and information specifying the individual or batch work unit in which the abnormality occurred. When work constituting the individual work unit in which the abnormality occurs is delivery of product PD by a mobile body MB, information for specifying the mobile body MB may be generated.

When it is determined that an abnormality has occurred, the abnormality determination part 72 transmits a resource readjustment instruction to the resource reallocation part 74. The basic function of the resource reallocation part 74 is common to that of the resource allocation part 62. Therefore, when the resource reallocation part 74 receives the resource reallocation instruction, the resource reallocation part 74 readjusts the resources to be input to the digital space DSP that reproduces the real space RSP including the individual or batch work unit determined to have the abnormality, and the DTS performing part 63 performs the DTS based on the information on the readjusted resource. That is, when it is determined that an abnormality has occurred, the DTS is executed.

As described above, when the DTS is executed, the calculation of the TWT is performed and the evaluation the TWT. In addition, until the convergent condition is satisfied, the adjustment (allocation) of the resources to be input to the digital space DSP, the calculation of the TWT, and the evaluation of the TWT are repeatedly performed. When the convergent condition is satisfied, allocation information on resources to be allocated to the real space RSP of the future time zone is generated and transmitted to the management servers 12 and 14. In this case, the management servers 12 and 14 perform allocation of a new resource, conversion of an already allocated resource, and the like based on the allocation information.

The alert generation part 73 generates alert information based on the abnormality occurrence information received from the abnormality determination part 72, and transmits the alert information to the management server 12 or 14. Since the abnormality occurrence information includes information for specifying the individual or batch work unit in which the abnormality has occurred, the alert generation part transmits the alert information to the management server 12 or 14 that manages the works constituting the individual or batch work unit.

### 5. Effect

According to the embodiment described above, the threshold TH is set in accordance with the tolerance to external factors. Therefore, in a case where multiple works are performed in cooperation with a plurality of work subjects, it is possible to detect occurrence of an abnormality in an individual or batch work unit with high accuracy. In addition, when an abnormality occurs in an individual or batch work unit, DTS is executed and allocation information on resources to be input to real space RSP of a future time zone is generated. Therefore, even if an abnormality occurs in an individual or batch work unit, the abnormal state can be quickly eliminated.

### 6. Other Services

In the embodiment, an example of a DTS using a digital space in which a logistics service LS is provided has been described. However, the present disclosure is also applicable to other services provided by a business operator (a vendor) to a business customer. Examples of the other services include a service related to supply of product PD and a service related to recycling of disused goods. In the service related to supply of product PD, for example, various works including production, subdivision, and packing of product PD requested by the business customer (e.g., a corporation customer) are performed at a base (e.g., a factory) of the business operator. In addition, delivery of the product PD to the destination DS (e.g., the logistics center group 20) is performed by the mobile body. In the disuse service, for example, collection of an article determined to be unnecessary by the business customer (e.g., an individual customer) and delivery to the destination DS (e.g., the factory of the business operator) are performed by a mobile body. In addition, various works such as disassembly, repair, and remanufacture of the collected article are performed in the destination DS (e.g., the factory of the business operator).

What is claimed is:

1. A method to manage a service provided from a business operator to a business customer, the method comprising the steps of:
executing a simulation using a digital space reproduced based on a real space in which the service is provided;
repeating the simulation until a simulation result satisfying a predetermined convergence condition is obtained; and
setting a threshold to detect an occurrence of an abnormality in one or more works related to the provision of the service in the real space for each work unit corresponding to the one or more works based on the simulation result in which the convergent condition is satisfied,
wherein, the step of setting the threshold comprises the steps of:
calculating, for each work unit, a simulation time difference indicating a time difference between a preset standard working time and a simulated work time included in the simulation result satisfying the convergent condition; and
setting a threshold corresponding to the simulation time difference to the work unit, wherein the work unit having a larger simulation time difference is given a threshold larger than that of the work unit having a smaller simulation time difference.

2. The method according to the claim 1,
wherein the work unit includes a batch work unit defined with respect to multiple works performed by a plurality of work subjects and an individual work unit defined with respect to individual works constituting the multiple works,
wherein the method further comprises the steps of:
calculating an actual work time in the one or more works for each work unit while the service is provided in the real space;
calculating a real time difference indicating a time difference between an actual work time of the batch or individual work unit and a standard working time preset for the batch or individual work unit; and
determining that an abnormality occurs in the individual work unit when the real time difference in the batch work unit is greater than the threshold set for the batch work unit and the real time difference in the individual work unit is greater than the threshold set for the individual work unit.

3. The method according to the claim 1,
wherein the work unit includes a batch work unit defined with respect to multiple works performed by the plurality of work subjects and an individual work unit defined with respect to individual works constituting the multiple works,
wherein the method further comprises the steps of:
calculating an actual work time in the one or more works for each work unit while the service is provided in the real space;
calculating a real time difference indicating a time difference between an actual work time of the batch or individual work unit and a standard working time preset for the batch or individual work unit; and
determining that an abnormality occurs in the batch work unit when the real time difference in the batch work unit is greater than the threshold set for the batch work unit and the real time difference in the individual work unit is less than the threshold set for the individual work unit.

4. The method according to the claim 2,
wherein the method further comprises the steps of:
when it is determined that the abnormality occurs in the individual work unit or the batch work unit, performing redistribution of resources to be input to the one or more works;
repeating the simulation until a new simulation result satisfying the convergent condition is obtained by using the digital space in which the resource reallocation is performed; and
resetting the threshold for each work unit based on the new simulation result.

5. A device to manage a service provided from a business operator to a business customer, comprising a processor configured to:
execute processing to simulate using a digital space reproduced based on a real space in which the service is provided;
execute processing to repeat the simulation until a simulation result satisfying a predetermined convergence condition is obtained; and
execute processing to set a threshold for detecting an occurrence of an abnormality in one or more works related to the provision of the service in the real space for each work unit corresponding to the one or more works based on the simulation result in which the convergent condition is satisfied,
wherein, in the processing to set the threshold, the processor is further configured to:
execute processing to calculate, for each work unit, a simulation time difference indicating a time difference between a preset standard working time and a simulated work time included in the simulation result satisfying the convergent condition; and
execute processing to set a threshold corresponding to the simulation time difference to the work unit
wherein, in the processing to set the threshold, the work unit having a large simulation time difference is assigned a threshold larger than that of the work unit having a small simulation time difference.

6. The device according to claim 5,
wherein the work unit includes a batch work unit defined with respect to multiple works performed by a plurality of work subjects and an individual work unit defined with respect to individual works constituting the multiple works,
wherein the processor is further configured to:
execute processing to calculate an actual work time in the one or more works for each work unit while the service is provided in the real space;
execute processing to calculate a real time difference indicating a time difference between an actual work time of the batch or individual work unit and a standard working time preset for the batch or individual work unit; and
execute processing to determine that an abnormality has occurred in the individual work unit when the real time difference in the batch work unit exceeds the threshold set for the batch work unit and the real time difference in the individual work unit exceeds the threshold set for the individual work unit.

7. The device according to claim 5,
wherein the work unit includes a batch work unit defined with respect to multiple works performed by the plurality of work subjects and an individual work unit defined with respect to individual works constituting the multiple works,
wherein the processor is further configured to:
execute processing to calculate an actual work time in the one or more works for each work unit while the service is provided in the real space;
execute processing to calculate a real time difference indicating a time difference between an actual work time of the batch or individual work unit and a standard working time preset for the batch or individual work unit; and
execute processing to determine that an abnormality has occurred in the batch work unit when the real time difference in the batch work unit exceeds the threshold set for the batch work unit and the real time difference in the individual work unit is less than the threshold set for the individual work unit.

8. The device according to claim 6,
wherein the processor is further configured to:
execute processing to redistribute resources to be input to the one or more works when it is determined that the abnormality has occurred in the individual work unit or the batch work unit;
execute processing to repeat the simulation until a new simulation result satisfying the convergent condition is obtained by using the digital space in which the resource reallocation is performed; and
execute processing to reset the threshold for each work unit based on the new simulation result.
